(19) United States
(12) Patent Application Publication
(10) Pub. No.: US 2017/0207359 A1
(43) Pub. Date: Jul. 20, 2017

(54) SOLAR CELL MODULE INCLUDING WIRING LAYER OVERLAPPINGLY DISPOSED ON SOLAR CELL

(71) Applicant: Panasonic Intellectual Property Management Co., Ltd., Osaka (JP)

(72) Inventors: Tasuku ISHIGURO, Osaka (JP); Youhei MURAKAMI, Osaka (JP); Masahiro IWATA, Osaka (JP)

(21) Appl. No.: 15/473,510

(22) Filed: Mar. 29, 2017

Related U.S. Application Data
(63) Continuation of application No. PCT/JP2015/003038, filed on Jun. 17, 2015.

(30) Foreign Application Priority Data
Sep. 30, 2014 (JP) 2014-201005

(51) Int. Cl. H01L 31/05; H01L 31/048; H01L 31/0216

(52) U.S. Cl. CPC H01L 31/0512; H01L 31/02167; H01L 31/0481

(57) ABSTRACT

A first insulating layer is layered on first surfaces of solar cells. Herein, the first insulating layer is formed of polyolefin or ethylene-vinyl acetate copolymer (EVA). A second insulating layer is layered on the first insulating layer. Herein, the second insulating layer is formed of polyester resin. A first inter-cell wire rod and second inter-cell wire rod provided to the first surfaces of the solar cells are partially brought into contact with the second insulating layer.

### CROSS-REFERENCE TO RELATED APPLICATION

This application is based upon and claims the benefit of priority from the prior Japanese Patent Application No. 2014-201005, filed on Sep. 30, 2014, the entire contents of which are incorporated herein by reference.

### BACKGROUND

1. Field

The disclosure relates to a solar cell module. Particularly, the disclosure relates to a solar cell module including wiring layers overlappingly provided to solar cells.

2. Description of the Related Art

A solar cell module includes a plurality of solar cells disposed therein. When lead-out wires are provided along a periphery of the plurality of solar cells, anon-power-generating area which does not contribute to power generation may be formed, which reduces an amount of power generation per unit area of the solar cell module. To improve the reduction in the amount of power generation per unit area, the lead-out wires are overlappingly provided to the solar cells (for example, see JP 2008-300449 A).

In a case where solar cells and lead-out wires are overlappingly provided, an insulating sheet is inserted therebetween to prevent connections between the lead-out wires and tab wires provided to the solar cells. In a case where the insulating sheet contains polyolefin or ethylene-vinyl acetate copolymer (EVA) and where the tab wires contain copper, the insulating sheet is oxidized and degraded by the copper.

### SUMMARY

The present invention has been made in light of such a situation, and an object of the present invention is to provide a technique for preventing degradation of the insulating sheet.

To solve the problem, a solar cell module according to an aspect includes solar cells, a first insulating layer layered on first surfaces of the solar cells, and a second insulating layer layered on the first insulating layer. The first insulating layer is formed of polyolefin or ethylene-vinyl acetate copolymer (EVA) and the second insulating layer is formed of polyester resin. Wire rods disposed on the first surfaces of the solar cells are partially brought into contact with the second insulating layer.

### BRIEF DESCRIPTION OF THE DRAWINGS

The figures depict one or more implementations in accordance with the present teaching, by way of example only, not byway of limitations. In the figures, like reference numerals refer to the same or similar elements.

FIG. 1 is a plane view of a solar cell module according to Example seen from a light-receiving-surface side;

FIG. 2 is a plane view of the solar cell module illustrated in FIG. 1 seen from a back-surface side;

FIG. 3 is a cross sectional view of the solar cell module illustrated in FIG. 1 taken along a y-axis;

FIG. 4 is a partial cross sectional view of the solar cell module illustrated in FIG. 1 taken along an x-axis;

FIG. 5 is a cross sectional view of an inter-cell wire rod illustrated in FIG. 4 taken along the x-axis;

FIG. 6 is a view illustrating a first process of a method for manufacturing the solar cell module illustrated in FIG. 1;

FIG. 7 is a view illustrating a second process of the method for manufacturing the solar cell module illustrated in FIG. 1; and

FIG. 8 is a view illustrating a third process of the method for manufacturing the solar cell module illustrated in FIG. 1.

### DETAILED DESCRIPTION

The invention will now be described by reference to the preferred embodiments. This does not intend to limit the scope of the present invention, but to exemplify the invention.

Before described in detail, the present invention will hereinafter be summarized. Example relates to a solar cell module provided with a plurality of solar cells disposed therein. A surface of each solar cell is provided with copper-containing tab wires for connecting adjacent solar cells. Furthermore, lead-out wires are overlappingly disposed on the tab wires so that electricity generated in the plurality of solar cells can be taken to the outside. An insulating sheet is inserted between the tab wires and lead-out wire to prevent connections therebetween. The insulating sheet has a three-layered structure. A second insulating layer formed of polyester resin is disposed in a middle of the three-layered structure, and a first insulating layer and third insulating layer are disposed to sandwich the second insulating layer. The first insulating layer and third insulating layer are formed of polyolefin or ethylene-vinyl acetate copolymer (EVA).

The polyester resin forming the second insulating layer is a hard material and is excellent in intensity. However, due to its high melting point, the polyester resin is hardly transformed during a lamination process and is insufficient in adhesiveness. To improve the adhesiveness, the first insulating layer and third insulating layer are applied. Herein, the first insulating layer is facing a solar cell side. When the first insulating layer absorbs the copper separated out from the tab wires, the first insulating layer is degraded due to oxidation. To reduce such degradation, the solar cell module according to the present Example is structured as follows.

Among surfaces included in each tab wire, a surface opposing the second insulating layer (hereinafter called “top surface”) is partially brought into contact with the second insulating layer. Therefore, the copper separated out from the top surface is sealed by the second insulating layer and becomes less diffusible in the first insulating layer. Among surfaces included in each tab wire, apart of surfaces (hereinafter called “side surfaces”) other than the top surface and a surface opposing the solar cells (hereinafter called “bottom surface”) is adhered to the first insulating layer. The remaining parts of the side surfaces are adhered to hollow portions without being adhered to the first insulating layer. In the first insulating layer, the hollow portions are included in parts ranging from parts adhering to the side surfaces to parts separated from and along the solar cells. The hollow portions are disposed in such manners so that the copper separated out from the side surfaces becomes less diffusible in the first insulating layer.

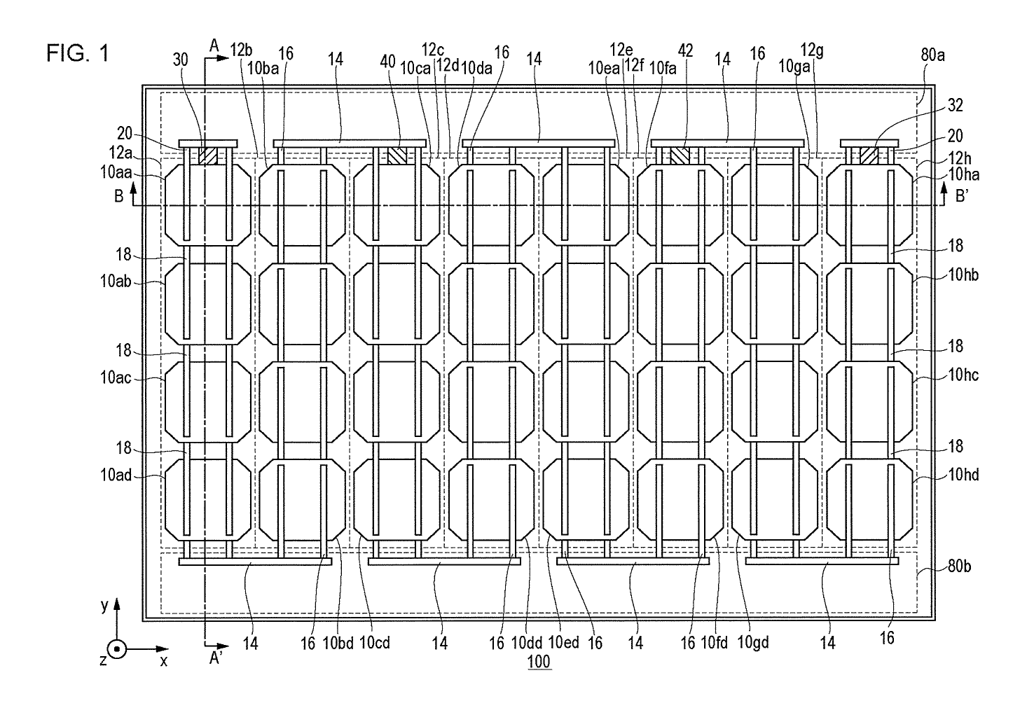

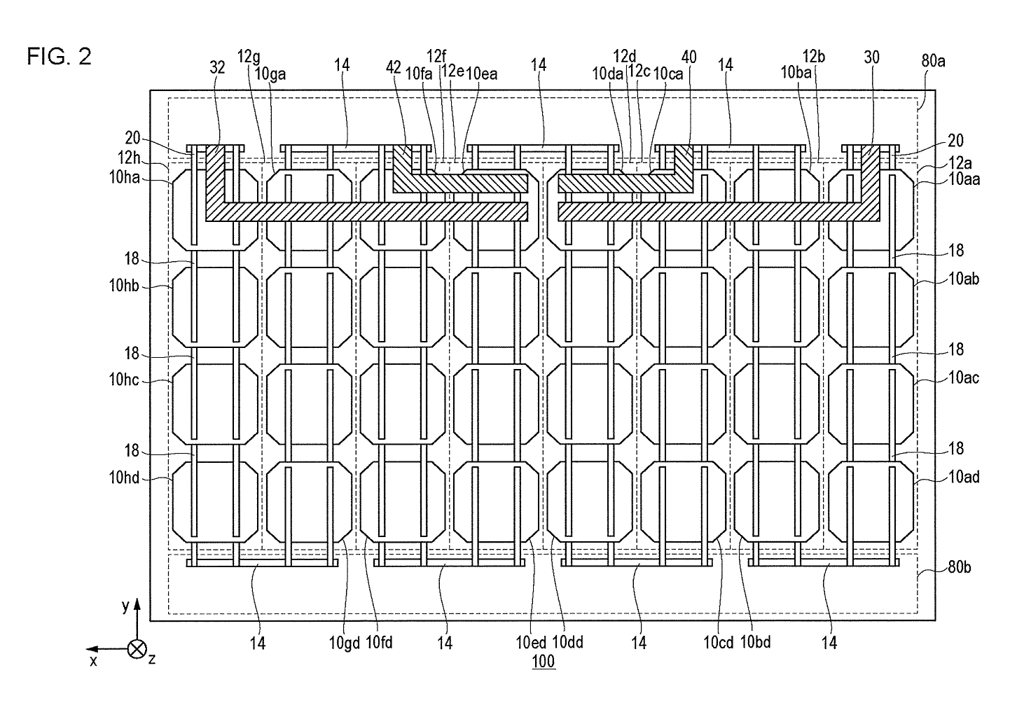

FIG. 1 is a plane view of a solar cell module 100 according to Example seen from a light-receiving-surface side. FIG. 2 is a place view of the solar cell module 100 seen from a back-surface side. As illustrated in FIG. 1, Cartesian coordinates including an x-axis, y-axis, and z-axis are defined. The x-axis and y-axis are perpendicular to each other in the plane view of the solar cell module 100. The z-axis vertical to the x-axis and y-axis stretches in a thickness direction of the solar cell module 100. Positive directions of the x-axis, y-axis, z-axis are defined by arrows in FIG. 1, and negative directions thereof are defined as directions opposing the arrows. Among two main surfaces included in the solar cell module 100 and parallel to an x-y plane, a main plane surface disposed in a positive direction side of the z-axis is a light receiving surface, and a main plane surface disposed in a negative direction side of the z-axis is a back surface. Hereinafter, the positive direction side of the z-axis is called the “light-receiving-surface side” and the negative direction side of the z-axis is called the “back-surface side”.

The solar cell module 100 includes an eleventh solar cell 10aa, . . . , and an eighty-fourth solar cell 10hd collectively called solar cells 10, inter-group wire rods 14, group-end wire rods 16, inter-cell wire rods 18, conductive materials 20, a first lead-out wire 30, a second lead-out wire 32, a first bypass diode connecting wire 40, and a second bypass diode connecting wire 42. A first non-power-generating area 80a and second non-power-generating area 80b are disposed to sandwich a plurality of solar cells 10 in the y-axial direction. Specifically, the first non-power-generating area 80a is disposed closer to the positive direction side of the y-axis than the plurality of solar cells 10, and the second non-power-generating area 80b is disposed closer to the negative direction side of the y-axis than the plurality of solar cells 10. Each of the first non-power-generating area 80a and second non-power-generating area 80b (hereinafter, those areas may be collectively called “non-power-generating areas 80”) has a rectangular shape and does not include the solar cells 10.

Each of the plurality of solar cells 10 absorbs incident light and generates photovoltaic power. The solar cells 10 are formed of semiconductor materials such as crystalline silicon, gallium arsenide (GaAs), and indium phosphide (InP). A structure of each solar cell 10 should not be restricted. Herein, for example, crystalline silicon and amorphous silicon are layered in each solar cell 10. Though omitted in FIG. 1 and FIG. 2, the light receiving surface and back surface of each solar cell 10 are provided with a plurality of finger electrodes stretching parallel to each other in the x-axial direction and provided with a plurality of, for example, two busbar electrodes stretching perpendicular to the plurality of finger electrodes in the y-axial direction. The busbar electrodes connect each of the plurality of finger electrodes.

The plurality of solar cells 10 is arranged in a matrix in the x-y plane. Herein, eight solar cells 10 are arranged in the x-axial direction and four solar cells 10 are arranged in the y-axial direction. The four solar cells 10 arranged in the y-axis are connected in series by the inter-cell wire rods 18 to form one solar battery group 12. For example, the eleventh solar cell 10aa, twelfth solar cell 10ab, thirteenth solar cell 10ac, and fourteenth solar cell 10ad are connected to form a first solar battery group 12a. Other solar battery groups 12, for example, from a second solar battery group 12b to eighth solar battery group 12h are formed similarly. Thus, eight solar battery groups 12 are arranged in parallel in the x-axial direction.

The inter-cell wire rods 18 connect the busbar electrodes in the light-receiving-surface side and the busbar electrodes in the back-surface side among the adjacent solar cells 10 to form one solar battery group 12. For example, two inter-cell wire rods 18 used for connecting the eleventh solar cell 10aa and twelfth solar cell 10ab electrically connect busbar electrodes in the back-surface side of the eleventh solar cell 10aa and busbar electrodes in the light-receiving-surface side of the twelfth solar cell 10ab.

Three among seven inter-group wire rods 14 are disposed in the first non-power-generating area 80a and the remaining four are disposed in the second non-power-generating area 80b. Each of the seven inter-group wire rods 14 stretches in the x-axial direction and is electrically connected to two solar battery groups 12 adjacent to each other through the group-end wire rods 16. For example, regarding the fourteenth solar cell 10ad disposed in a second non-power-generating area 80b side of the first solar battery group 12a and the twenty-fourth solar cell 10bd disposed in a second non-power-generating area 80b side of the second solar battery group 12b, they are electrically connected to one inter-group wire rod 14 through the group-end wire rods 16. Furthermore, the inter-group wire rods 14 are electrically connected to the first bypass diode connecting wire 40 and second bypass diode connecting wire 42. Regarding the first bypass diode connecting wire 40 and second bypass diode connecting wire 42, they will be described later.

The first solar battery group 12a and eighth solar battery group 12h disposed in both ends of the x-axial direction are connected to the conductive materials 20. The conductive materials 20 connected to the first solar battery group 12a stretch from the light-receiving-surface side of the eleventh solar cell 10aa toward the first non-power-generating area 80a. The conductive materials 20 are connected to a pair of positive and negative first lead-out wire 30 and second lead-out wire 32 by a conductive adhesive such as solder. Therefore, the first lead-out wire 30 is electrically connected to the first solar battery group 12a through the conductive materials 20, and the second lead-out wire 32 is electrically connected to the eighth solar battery group 12h through the conductive materials 20.

The first lead-out wire 30 stretches from a position where it is soldered to the conductive materials 20 toward the back-surface side of the eleventh solar cell 10aa. Furthermore, the first lead-out wire 30 stretches in the negative direction of the y-axis in the back-surface side of the eleventh solar cell 10aa and then bends in the positive direction of the x-axis. In such manners, the first lead-out wire 30 is disposed in the back-surface side of the eleventh solar cell 10aa, twenty-first solar cell 10ba, thirty-first solar cell 10ca, and forty-first solar cell 10da along the x-axis. Herein, the first lead-out wire 30 is separated in the z-axial direction from the group-end wire rods 16 and inter-cell wire rods 18 provided to the back-surface side of the eleventh solar cell 10aa, twenty-first solar cell 10ba, thirty-first solar cell 10ca, and forty-first solar cell 10da. It should be noted that the group-end wire rods 16 and inter-cell wire rods 18 correspond to the tab wires. The second lead-out wire 32 is similarly disposed with respect to the eighty-first solar cell 10ha, seventy-first solar cell 10ga, sixty-first solar cell 10fa, and fifty-first solar cell 10ea.

Hereinafter described are structures of the first bypass diode connecting wire 40 and second bypass diode connecting wire 42. Two group-end wire rods 16 stretch from the back-surface side of the twenty-first solar cell 10ba in the second solar battery group 12b toward the first non-power-generating area 80a. Furthermore, another two group-end wire rods 16 stretch from the light-receiving-surface side of the thirty-first solar cell 10ca in the third solar battery group 12c toward the first non-power-generating area 80a. The inter-group wire rod 14 is electrically connected to these four group-end wire rods 16 by the conductive adhesive such as solder. The first bypass diode connecting wire 40 is disposed between the two group-end wire rods 16 and is electrically connected to the inter-group wire rod 14 by the conductive adhesive such as solder.

The first bypass diode connecting wire 40 stretches from a position where it is soldered to the inter-group wire rod 14 toward the back-surface side of the thirty-first solar cell 10ca. Furthermore, the first bypass diode connecting wire 40 stretches in the negative direction of the y-axis in the back-surface side of the thirty-first solar cell 10ca and then bends in the positive direction of the x-axis. In such manners, the first bypass diode connecting wire 40 is disposed in the back-surface side of the thirty-first solar cell 10ca and forty-first solar cell 10da, parallel to the first lead-out wire 30 along the x-axis. Similar to the first lead-out wire 30, the first bypass diode connecting wire 40 is separated in the z-axial direction from the group-end wire rods 16 and inter-cell wire rods 18 provided to the back-surface side of the thirty-first solar cell 10ca and forty-first solar cell 10da. The second bypass diode connecting wire 42 is similarly disposed with respect to the sixty-first solar cell 10fa and fifty-first solar cell 10ea.

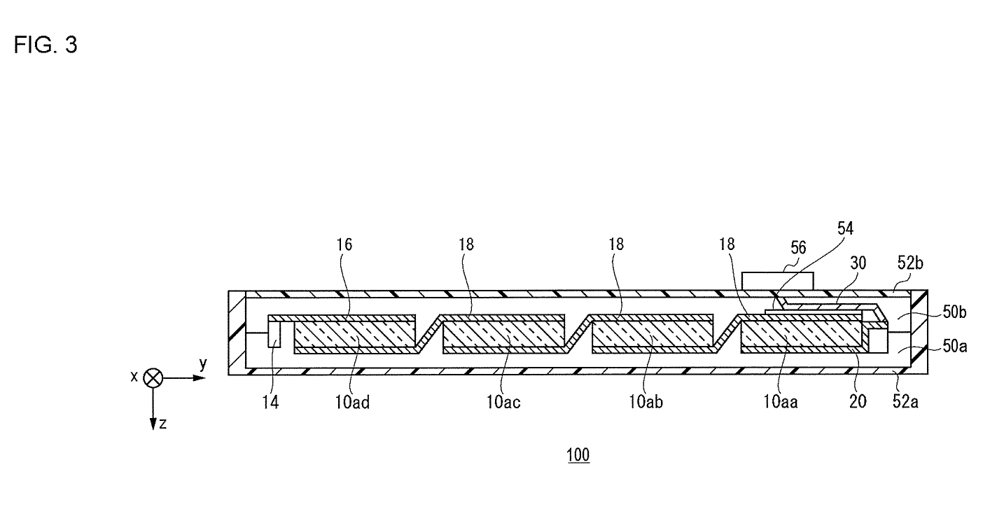

FIG. 3 is a cross sectional view of the solar cell module 100 taken along the y-axis and a line A-A′ in FIG. 1. The solar cell module 100 includes the eleventh solar cell 10aa, twelfth solar cells 10ab, thirteenth solar cell 10ac, and fourteenth solar cell 10ad collectively called the solar cells 10, the inter-group wire rods 14, the group-end wire rods 16, the inter-cell wire rods 18, the conductive materials 20, a first encapsulant 50a and a second encapsulant 50b collectively called encapsulants 50, a first protective member 52a and a second protective member 52b collectively called protective members 52, insulating layers 54, and a terminal box 56. An upper side of FIG. 3 corresponds to the back-surface side and a lower side thereof corresponds to the light-receiving-surface side.

The first protective member 52a is disposed in the light-receiving-surface side of the solar cell module 100 and protects the light receiving surfaces of the solar cell module 100. Applicable examples of the first protective member 52a include a translucent and impervious glass, and translucent plastic. The first protective member 52a is formed in a rectangular shape. The first encapsulant 50a is layered in the back-surface side of the first protective member 52a. The first encapsulant 50a is disposed between the first protective member 52a and the solar cells 10 and adheres them. An applicable example of the first encapsulant 50a includes thermoplastic resin like a resin film such as polyolefin, EVA, polyvinyl butyral (PVB), and polyimide. It should be noted that thermosetting resin is also applicable. The first encapsulant 50a is translucent and is formed by a rectangular sheet including a surface with a size substantially equal to that of the x-y plane in the first protective member 52a.

The second encapsulant 50b is layered in the back-surface side of the first encapsulant 50a. The second encapsulant 50b seals the plurality of solar cells 10, inter-cell wire rods 18, and the like disposed between the first encapsulant 50a and second encapsulant 50b. A material similar to the first encapsulant 50a may be used as the second encapsulant 50b. Furthermore, the second encapsulant 50b and first encapsulant 50a may be combined by heating in a lamination and curing process.

The second protective member 52b is layered in the back-surface side of the second encapsulant 50b. The second protective member 52b performing as back sheet protects the back-surface side of the solar cell module 100. An applicable example of the second protective member 52b includes a layered film having a structure in which resin films sandwich a resin film such as polyethylene terephthalate (PET) and aluminum (Al) foil. The second protective member 52b is provided with an opening (not illustrated) penetrating the protective member in the z-axial direction.

The terminal box 56 is formed in a cuboid shape and is adhered to the back-surface side of the second protective member 52b by an adhesive such as silicone to cover the opening (not illustrated) of the second protective member 52b. The pair of positive and negative first lead-out wire 30 and second lead-out wire 32, first bypass diode connecting wire 40, and second bypass diode connecting wire 42 are induced to a bypass diode (not illustrated) stored in the terminal box 56. Herein, the terminal box 56 is disposed at a position overlapping with the forty-first solar cell 10da and fifty-first solar cells 10ea upon the second protective member 52b A frame including aluminum (Al) and the like may be circumferentially attached to the solar cell module 100.

As mentioned above, the first lead-out wire 30 is separated in z-axial direction from the inter-cell wire rods 18 provided to the back-surface side of the eleventh solar cell 10aa. In such a structure, to prevent connections between the first lead-out wire 30 and inter-cell wire rods 18, the insulating layers 54 are inserted therebetween. A structure of each insulating layer 54 will be described later. It should be noted that, in FIG. 2, each insulating layer 54 has a size in the x-y plane which can cover overlapping portions of the eleventh solar cell 10aa, twenty-first solar cell 10ba, thirty-first solar cell 10ca, forty-first solar cell 10da, and the first lead-out wire 30 as well as overlapping portions of the solar cells and the first bypass diode connecting wire 40. Furthermore, another insulating layers 54 are inserted with respect to the second lead-out wire 32 and second bypass diode connecting wire 42 illustrated in FIG. 2. It should be noted that the insulating layers 54 and another insulating layers 54 may be combined.

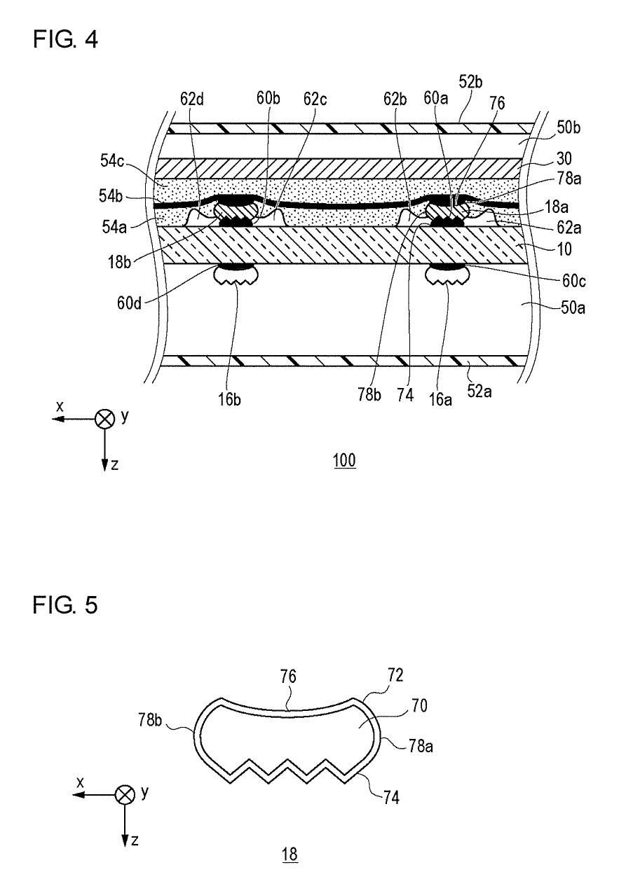

FIG. 4 is a partial cross sectional view of the solar cell module 100 taken along the x-axis and a line B-B′ in FIG. 1. The solar cell module 100 includes the solar cells 10, a first group-end wire rod 16a and a second group-end wire rod 16b collectively called the group-end wire rods 16, a first inter-cell wire rod 18a and a second inter-cell wire rod 18b collectively called the inter-cell wire rods 18, a first encapsulant 50a and a second encapsulant 50b collectively called the encapsulants 50, a first protective member 52a and a second protective member 52b collectively called the protective members 52, a first insulating layer 54a, a second insulating layer 54b, and a third insulating layer 54c collectively called the insulating layers 54, a first resin layer 60a, a second resin layer 60b, a third resin layer 60c, and a fourth resin layer 60d collectively called the resin layers 60, a first hollow portion 62a, a second hollow portion 62b, a third hollow portion 62c, and a fourth hollow portion 62d collectively called the hollow portions 62.

Each inter-cell wire rod 18 has recesses and protrusions in a first-surface side. Each of the protrusions among the recesses and protrusions in the first-surface side has a conical shape substantially like a triangular prism. Herein, a structure of each inter-cell wire rod 18 will be described in detail with reference to FIG. 5. FIG. 5 is a cross sectional view of one inter-cell wire rod 18 taken along the x-axis. Each inter-cell wire rod 18 includes a core 70 and coating material 72. The core 70 is disposed in a middle portion of each inter-cell wire rod 18 and is formed of copper. The coating material 72 is disposed to surround the core 70 and is formed of a material different from copper such as silver and solder.

In the light-receiving-surface side of each inter-cell wire rod 18, a plurality of conical shaped protrusions 74 are disposed in line in the x-axial direction. On the other hand, in the back-surface side of each inter-cell wire rod 18, a curved surface 76 is disposed. The curved surface 76 has a curved shape caved in the light-receiving-surface side. Therefore, both ends of the curved surface 76 in the x-axial direction protrude in a direction of the back-surface side. A first side surface 78a and second side surface 78b (hereinafter, they may be collectively called “side surfaces 78”) are sandwiched by the curved surface 76 and the surface in which the protrusions 74 are disposed. Each side surface 78 has a shape swelling outward in the y-axial direction. It should be noted that the curved surface 76 and the side surfaces 78 may be flat or may include a plurality of fine recesses and protrusions in each surface. The expression “fine” represents sufficiently smaller than the shortest length among a length direction, width direction, and thickness direction of the protrusions 74. In the first inter-cell wire rod 18a and second inter-cell wire rod 18b in FIG. 4, the surface in which the protrusions 74 are disposed corresponds to the bottom surface, the curved surface 76 corresponds to the top surface, and the side surfaces 78 correspond to the side surfaces. Referring back to FIG. 4.

Each group-end wire rod 16 has a structure similar to that of each inter-cell wire rod 18. It should be noted that a cross sectional shape of each group-end wire rod 16 may be different from that of each inter-cell wire rod 18. The resin layers 60 adhere the inter-cell wire rods 18 and the busbar electrodes (not illustrated) disposed in the back surfaces of the solar cells 10. The resin layers 60 further adhere the group-end wire rods 16 and the busbar electrodes disposed in the light receiving surfaces of the solar cells 10. More specifically, in the inter-cell wire rods 18, the surface in which the protrusions 74 are disposed is adhered to the busbar electrodes by the resin layers 60. Furthermore, in the group-end wire rods 16, the curved surface 76 is adhered to the busbar electrodes by the resin layers 60. Due to such adhesion by the resin layers 60, the busbar electrodes and inter-cell wire rods 18 are electrically conducted, and the busbar electrodes and group-end wire rods 16 are also electrically conducted. The resin layers 60 are adhesive layers obtained by hardening a resin adhesive. The resin layers 60 are formed of, for example, a thermosetting resin material having adhesiveness such as epoxy resin, acrylic resin, and urethane resin.

The insulating layers 54 include three layers, that is, the first insulating layer 54a, second insulating layer 54b, and third insulating layer 54c overlappingly disposed in the z-axial direction. The insulating layers 54 are inserted between the solar cells 10 and the first lead-out wire 30. The first insulating layer 54a is disposed in a solar-cell 10 side, and the third insulating layer 54c is disposed in a first-lead-out-wire 30 side. Therefore, the first insulating layer 54a is layered on the back-surface side of the solar cells 10, the second insulating layer 54b is layered on the back-surface side of the first insulating layer 54a, and the third insulating layer 54c is layered on the back-surface side of the second insulating layer 54b.

As mentioned above, the first insulating layer 54a and third insulating layer 54c are formed of polyolefin or EVA The first insulating layer 54a and third insulating layer 54c may be formed of a similar material or different material. Furthermore, the second insulating layer 54b is formed of polyester resin. An example of the polyester resin is PET. As mentioned above, the polyester resin is a hard fiber and is excellent in intensity. However, due to its high melting point, the polyester resin is hardly dissoluble in the lamination process. Therefore, when the second insulating layer 54b is inserted between the inter-cell wire rods 18 and the first lead-out wire 30, the inter-cell wire rods 18 and the first lead-out wire 30 are sufficiently insulated but insufficiently adhered. To improve the adhesiveness, the first insulating layer 54a and third insulating layer 54c are included in the insulating layers 54 to be used to sandwich the second insulating layer 54b from both surfaces.

In such a structure, the core 70 of each inter-cell wire rod 18 is formed of copper so that the copper is separated out from each inter-cell wire rod 18. When the separated copper soaks into the first insulating layer 54a formed of polyolefin or EVA, the first insulating layer 54a is degraded due to oxidation. To reduce oxidation degradation of the first insulating layer 54a, the first insulating layer 54a and second insulating layer 54b are disposed in the following manners.

The inter-cell wire rods 18 provided to the back-surface side of the solar cells 10 are partially and directly in contact with the second insulating layer 54b. More specifically, the curved surface 76 of the first inter-cell wire rod 18a is in contact with the second insulating layer 54b. Herein, the whole curved surface 76 should not be necessarily in contact with the second insulating layer 54b. Apart of the curved surface 76 may be in contact with the second insulating layer 54b. “A part” represents, for example, 50% or more of the whole surface, and more preferably, 70% or more. Due to such connections, even when the copper is separated out from the curved surface 76, the copper is easily accumulated between the second insulating layer 54b and the curved surface 76. Thus, an amount of the copper soaking into the first insulating layer 54a becomes small, which reduces the oxidation degradation.

The inter-cell wire rods 18 are adhered to the first insulating layer 54a at least at some parts of the side surfaces 78. The inter-cell wire rods 18 are adhered to the hollow portions 62 at the remaining parts. Herein, the side surfaces 78 are surfaces other than the surface opposing the second insulating layer 54b and the curved surface 76 within each inter-cell wire rod 18. The hollow portions 62 are a collective term of the first hollow portion 62a to fourth hollow portion 62d. The first hollow portion 62a is formed to be in contact with the first side surface 78a, and the second hollow portion 62b is formed to be in contact with the second side surface 78b. Even when the copper is separated out from the parts within the side surfaces 78 in contact with the hollow portions 62, the hollow portions 62 prevent the copper from soaking into the first insulating layer 54a.

Furthermore, there are the hollow portions 62 in parts within the first insulating layer 54a ranging from the parts adhering to the side surfaces 78 to the parts separated from and along the solar cells 10 in the x-axial direction. Therefore, even when the copper is separated out from the adhering parts, the hollow portions 62 prevent the copper from diffusing. Thus, the amount of the copper soaking into the first insulating layer 54a can be reduced. The insulating layers 54 include such structures that a thickness of the first insulating layer 54a, for example, a thickness of polyolefin or EVA is made to be ranging from 100 μm to 200 μm, and a thickness of each inter-cell wire rod 18 is made to be ranging from 200 μm to 300 μm. Furthermore, vacuum lamination is carried out at a temperature about 150° C. in the lamination and curing process which is to be mentioned later. In such manners, the hollow portions 62 are generated by controlling the thickness of polyolefin or EVA and by controlling lamination conditions (temperature). It should be noted that the heat applied during the lamination and curing process melts the first insulating layer 54a and third insulating layer 54c and allows them to flow easily. When the first insulating layer 54a and third insulating layer 54c start flowing, stress in the x-axial direction is applied to the inter-cell wire rods 18, which degrades reliability of the solar cell module 100. However, according to the present Example, the second insulating layer 54b and curved surface 76 are directly in contact with each other so that even in a case where the first insulating layer 54a and third insulating layer 54c flow, the second insulating layer 54b may not flow easily. Thus, the stress with respect to the inter-cell wire rods 18 in the x-axial direction is reduced, which improves reliability of the solar cell module 100.

The second encapsulant 50b is layered in the back-surface side of the third insulating layer 54c. The first lead-out wire 30 is provided between the second encapsulant 50b and third insulating layer 54c. As mentioned before, the first lead-out wire 30 is connected to the solar cells 10. In the description above, it should be noted that the first lead-out wire 30 may be the second lead-out wire 32, the first bypass diode connecting wire 40, or the second bypass diode connecting wire 42. Furthermore, the inter-cell wire rods 18 are disposed in the back-surface side and the group-end wire rods 16 are disposed in the light-receiving-surface side, but the group-end wire rods 16 and conductive materials 20 may be disposed in the back-surface side, and the inter-cell wire rods 18 and conductive materials 20 may be disposed in the light-receiving-surface side.

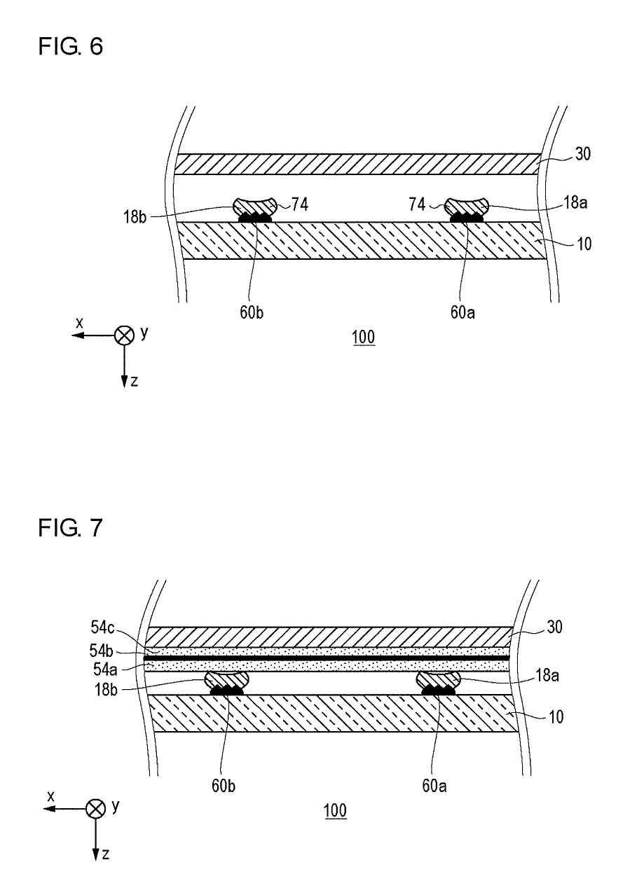

Hereinafter, a method for manufacturing the solar cell module 100 will be described. To make the description clear, it should be noted that the method for manufacturing the back-surface side of the solar cells 10 will be described. FIG. 6 is a view illustrating a first process of the method for manufacturing the solar cell module 100. First, the solar cells 10 are prepared and the adhesive is applied to the surfaces of the solar cells 10 to adhere the inter-cell wire rods 18. Herein, the adhesive is applied to cover the busbar electrodes by a discharging unit such as a dispenser or by screen printing. It should be noted that when the adhesive is a resin adhesive film, the resin adhesive film may be attached to cover the busbar electrodes. Next, the inter-cell wire rods 18 are disposed on the busbar electrodes. Thereafter, the inter-cell wire rods 18 are pressed in a state that each surface in which the protrusions 74 are disposed is in contact with the busbar electrodes. Furthermore, the adhesive is hardened by heating. Accordingly, the adhesive is hardened to become the resin layers 60, thereby forming the resin layers 60. Furthermore, the first lead-out wire 30 is connected to the back-surface side of the solar cells 10.

FIG. 7 is a view illustrating a second process of the method for manufacturing the solar cell module 100. The insulating layers 54 are inserted between the first lead-out wire 30 and the solar cells 10. Herein, the first insulating layer 54a is disposed to face the solar cells 10 and the third insulating layer 54c is disposed to face the first lead-out wire 30.

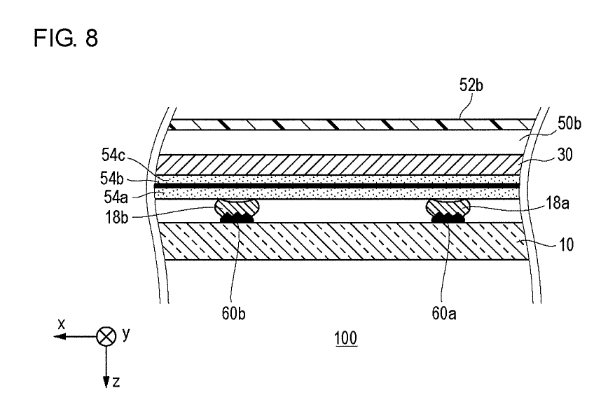

FIG. 8 is a view illustrating a third process of the method for manufacturing the solar cell module 100. The second encapsulant 50b is layered in the back-surface side of the first lead-out wire 30. Furthermore, the second protective member 52b is layered in the back-surface side of the second encapsulant 50b. It should be noted that the light-receiving-surface side of the solar cells 10 is also layered as illustrated in FIG. 4, and a layered structure is formed.

Consequently, the lamination and curing process is carried out with respect to the layered structure. In this process, by pressuring the layered structure under reduced pressure, the air inside the layered structure is deflated and the layered structure is heated so that the layered structure is combined. As mentioned above, during the vacuum laminating in the lamination and curing process, the temperature is set at about 150° C. Furthermore, the terminal box 56 is attached to the second protective member 52b by the adhesive.

According to Example, the inter-cell wire rods 18 are partially in contact with the second insulating layer 54b so that even when the copper is separated out from the surfaces in a second-insulating-layer 54b side of the inter-cell wire rods 18, the copper can be accumulated between the inter-cell wire rods 18 and the second insulating layer 54b. Since the copper is accumulated between the inter-cell wire rods 18 and the second insulating layer 54b, it is possible to prevent the copper from soaking into the first insulating layer 54a. Since the copper is prevented from soaking into the first insulating layer 54a, the degradation of the insulating sheet can be prevented. Furthermore, since the inter-cell wire rods 18 are partially in contact with the second insulating layer 54b, even when the first insulating layer 54a flows at high temperature, it is possible to prevent a situation that the second insulating layer 54b also flows. Since the flowing of the second insulating layer 54b is prevented, the stress applied to the inter-cell wire rods 18 can be reduced.

Furthermore, at least some parts of the side surfaces 78 are adhered to the first insulating layer 54a and the remaining parts are brought into contact with the hollow portions 62. Therefore, even when the copper is separated out from the hollow portions 62, the copper can be prevented from soaking into the first insulating layer 54a. Still further, at least some parts of the side surfaces 78 are adhered to the first insulating layer 54a and the remaining parts are brought into contact with the hollow portions 62 so that the inter-cell wire rods 18 and the second insulating layer 54b can be stabilized by the first insulating layer 54a. Still further, there are the hollow portions 62 in the parts ranging from the parts adhering to the side surfaces 78 to the parts separated from and along the solar cells 10. Therefore, the copper which has soaked into the first insulating layer 54a can be prevented from diffusing. Each inter-cell wire rod 18 includes the core 70 and coating material 72 so that the copper can be protected by silver or solder. The third insulating layer 54c is layered on the second insulating layer 54b, and the first lead-out wire 30 and the like are layered on the third insulating layer 54c so that it is possible to avoid connections between the inter-cell wire rods 18 and the first lead-out wire 30 and the like.

The present invention has been described based on the Example above. Example herein is for illustration purpose and it is obvious to those skilled in the art that combinations of each structural element or each process can be modified variously and that such modifications are also within the range of the present invention.

A summary of the present Example is as follows. The solar cell module 100 according to an aspect of the present invent ion includes the solar cells 10, the first insulating layer 54a layered on the first surfaces of the solar cells 10, and the second insulating layer 54b layered on the first insulating layer 54a. The first insulating layer 54a is formed of polyolefin or ethylene-vinyl acetate copolymer (EVA), and the second insulating layer 54b is formed of polyester resin. The inter-cell wire rods 18 disposed on the first surfaces of the solar cells 10 are partially brought into contact with the second insulating layer 54b.

The inter-cell wire rods 18 is adhered to the first insulating layer 54a at least at some parts of the surface other than the surface opposing the solar cells 10 and the surface opposing the second insulating layer 54b. The first insulating layer 54a may include the hollow portions 62 in the parts ranging from the parts adhering to the inter-cell wire rods 18 to the parts separated from and along the solar cells 10.

The inter-cell wire rods 18 may include the core 70 formed of copper, and the coating material 72 formed of a material different from copper.

The solar cell module 100 may further include the third insulating layer 54c layered on the second insulating layer 54b, the encapsulant 50 layered on the third insulating layer 54c, and the first lead-out wire 30 provided between the encapsulant 50 and third insulating layer 54c and connected to the solar cells 10. The third insulating layer 54c may be formed of polyolefin or EVA.

While the foregoing has described what are considered to be the best mode and/or other examples, it is understood that various modifications may be made therein and that the subject matter disclosed herein may be implemented in various forms and examples, and that they may be applied innumerous applications, only some of which have been described herein. It is intended by the following claims to claim any and all modifications and variations that fall within the true scope of the present teachings.

What is claimed is:

1. A solar cell module comprising:
a solar cell;
a first insulating layer layered on a first surface of the solar cell;
a second insulating layer layered on the first insulating layer, wherein
the first insulating layer is formed of polyolefin or ethylene-vinyl acetate copolymer (EVA),
the second insulating layer is formed of polyester resin, and
a wire rod disposed on the first surface of the solar cell is partially brought into contact with the second insulating layer.

2. The solar cell module according to claim 1, wherein
the wire rod is adhered to the first insulating layer at least at a part of a surface other than a surface opposing the solar cell and a surface opposing the second insulating layer, and
the first insulating layer includes a hollow portion in a part ranging from a part adhering to the surface of the wire rod to a part separated from and along the solar cell.

3. The solar cell module according to claim 1, wherein the wire rod includes a core formed of copper and a coating material formed of a material different from copper.

4. The solar cell module according to claim 2, wherein the wire rod includes a core formed of copper and a coating material formed of a material different from copper.

5. The solar cell module according to claim 1, further comprising:
a third insulating layer layered on the second insulating layer;
a protective layer layered on the third insulating layer; and
a wiring layer provided between the protective layer and the third insulating layer and connected to the solar cell, wherein
the third insulating layer is formed of polyolefin or EVA.

6. The solar cell module according to claim 2, further comprising:
a third insulating layer layered on the second insulating layer;
a protective layer layered on the third insulating layer; and
a wiring layer provided between the protective layer and the third insulating layer and connected to the solar cell, wherein
the third insulating layer is formed of polyolefin or EVA.

7. The solar cell module according to claim 3, further comprising:
a third insulating layer layered on the second insulating layer;
a protective layer layered on the third insulating layer; and
a wiring layer provided between the protective layer and the third insulating layer and connected to the solar cell, wherein
the third insulating layer is formed of polyolefin or EVA.

8. The solar cell module according to claim 4, further comprising:
a third insulating layer layered on the second insulating layer;
a protective layer layered on the third insulating layer; and
a wiring layer provided between the protective layer and the third insulating layer and connected to the solar cell, wherein
the third insulating layer is formed of polyolefin or EVA.
